(19) United States
(12) Patent Application Publication
(10) Pub. No.: US 2025/0226649 A1
(43) Pub. Date: Jul. 10, 2025

(54) LEAKAGE CURRENT DETECTION AND INTERRUPTION DEVICE FOR POWER CORD AND RELATED ELECTRICAL CONNECTORS AND ELECTRICAL APPLIANCES

(71) Applicant: Chengli LI, Suzhou (CN)

(72) Inventors: Chengli LI, Suzhou (CN); Long CHEN, Suzhou (CN)

(73) Assignee: Chengli LI, Suzhou (CN)

(21) Appl. No.: 19/095,487

(22) Filed: Mar. 31, 2025

Related U.S. Application Data
(63) Continuation-in-part of application No. 18/347,012, filed on Jul. 5, 2023, now Pat. No. 12,292,474.

(30) Foreign Application Priority Data
Jun. 30, 2023 (CN) 202310790448.7
Jun. 30, 2023 (CN) 202321691997.0
Mar. 26, 2025 (CN) 202520541328.8

(51) Int. Cl. H02H 3/16; G01R 31/52; H01H 83/02; H02H 7/22

(52) U.S. Cl. CPC H02H 3/16; G01R 31/52; H01H 83/02; H02H 7/228

(57) ABSTRACT

A leakage detection protection device includes: a switch module; a leakage detection module including first and second leakage detection lines connected in series at one end, for generating a leakage fault signal when a leakage current signal is detected; a monitoring module for detecting whether the first and/or second leakage detection line has a fault, and for generating a detection fault signal when a fault is detected; a drive module for driving the switch module to disconnect power connection in response to the leakage fault signal and/or the detection fault signal; and a functional redundancy module, including at least one redundant element, connected in series or in parallel with at least one element in the monitoring module and/or the drive module, for providing the same function as the at least one element when it has a fault. This device can provide a redundant function when some elements are damaged.

### BACKGROUND OF THE INVENTION

This invention relates to electrical circuits, and in particular, it relates to a leakage current detection and interruption (LCDI) device for a power cord, and related electrical connectors and electrical appliances.

Leakage current detection and interruption (LCDI) device is a fire hazard prevention device for electrical appliances. It is implemented in a power cord with a plug, and functions to detect any leakage current between the hot and neutral power supply lines and their shield layers along the power cord from the plug to the electrical load (e.g., air conditioner, dehumidifier, etc.). When a leakage current is detected, the LCDI device can disconnect the electrical power from the power source to the appliance, preventing fire hazard and ensuring safety. Thus, LCDI devices can prevent fire hazard caused by arc fault due to physical damage and loss of insulation in the power cord, which may be caused by aging of the hot, neutral and ground wires, wear, pinching, animal chewing, etc.

When some components of the existing LCDI device are damaged and the intended functions fail, the device cannot immediately send out an indication signal to remind the user or prevent the user from using the device, therefore posing a potential safety hazard in electricity use.

### SUMMARY OF THE INVENTION

To address problems of the conventional art, in one aspect, the present invention provides a leakage current detection and interruption device, which includes: power supply lines including a first current-carrying line and a second current-carrying line, having an input end and an output end; a switch module, configured to control a power connection between the input end and the output end; a leakage detection module, including a first leakage detection line and a second leakage detection line connected in series at one end, wherein the first leakage detection line covers the first current-carrying line and is configured to detect a leakage current signal on the first current-carrying line, and the second leakage detection line covers the second current-carrying line and is configured to detect a leakage current signal on the second current-carrying line, and the leakage detection module is configured to generate a leakage fault signal when the first leakage detection line and/or the second leakage detection line detects the leakage current signal; a monitoring module, connected in series with the first leakage detection line and the second leakage detection line and connected to the first current-carrying line and the second current-carrying line, and configured to detect whether the first leakage detection line and/or the second leakage detection line has a fault and to generate a detection fault signal when a fault occurs; a drive module, connected to the switch module, the leakage detection module and the monitoring module, and configured to drive the switch module to disconnect the power connection in response to the leakage fault signal and/or the detection fault signal; and a functional redundancy module, including at least one redundant element, wherein the at least one redundant element is connected in series or in parallel with at least one element of the monitoring module and/or the drive module and configured to provide a replacement function that replaces the at least one element when the at least one element has a fault.

In some embodiments, the monitoring module includes a first resistor, wherein one end of the first resistor is connected to another end of the first current-carrying line, and another end of the first resistor is connected to another end of the second leakage detection line and connected to the drive module, and wherein the at least one redundant element includes a third resistor connected in parallel with the first resistor.

In some embodiments, the monitoring module includes a second resistor, wherein one end of the second resistor is connected to the other end of the first leakage detection line and another end of the second resistor is connected to the drive module, and wherein the at least one redundant element includes a fourth resistor connected in parallel with the second resistor.

In some embodiments, the drive module includes: a solenoid configured to generate an electromagnetic force for driving the switch module; and at least one semiconductor element, connected in series with the solenoid, wherein the semiconductor element is triggered to turn on in response to the leakage fault signal and/or the detection fault signal, wherein the solenoid generates the electromagnetic force when the semiconductor is turned on.

In some embodiments, the drive module further includes a first diode, wherein an anode of the first diode is connected to a cathode of the at least one semiconductor element and a cathode of the first diode is connected to the first current-carrying line, and the at least one redundant element includes a third diode connected in parallel with the first diode.

In some embodiments, the drive module further includes a second diode, wherein an anode of the second diode is connected to a cathode of the at least one semiconductor element and a cathode of the second diode is connected to the solenoid, and wherein the at least one redundant element includes a fourth diode connected in parallel with the second diode.

In some embodiments, the drive module includes a first capacitor and a first voltage regulator diode, wherein an anode of the first voltage regulator diode is connected to a control electrode of the at least one semiconductor element, and a cathode of the first voltage regulator diode is connected to the leakage detection module and the monitoring module, and two ends of the first capacitor are respectively connected to a cathode of the at least one semiconductor element and the cathode of the first voltage regulator diode, and wherein the at least one redundant element includes: a third capacitor connected in series or in parallel with the first capacitor; and/or a second voltage regulator diode connected in series or in parallel with the first voltage regulator diode.

In some embodiments, the drive module further includes a fifth resistor, wherein one end of the fifth resistor is connected to the cathode of the first voltage regulator diode and one end of the first capacitor, and another end of the fifth resistor is connected to the monitoring module, and wherein the at least one redundant element includes a sixth resistor is connected in series or in parallel with the fifth resistor.

In some embodiments, the drive module includes a second capacitor, wherein two ends of the second capacitor are respectively connected to a cathode and a control electrode of the at least one semiconductor element, and wherein the at least one redundant element includes a fourth capacitor connected in series with the second capacitor.

In another aspect, the present invention provides an electrical power connection device, which includes: a body; and a leakage current detection and interruption device of claim 1, disposed inside the body.

In another aspect, the present invention provides an electrical appliance, which includes: an electrical load; and an electrical power connection device of claim 10 connected between a power supply and the electrical load, configured to supply power to the electrical load.

In embodiments of the present invention, the leakage current detection and interruption device includes a functional redundancy module, which can provide a redundant function for at least one element in the monitoring module and/or the drive module, so as to provide the same function as the at least one element when it fails, so that the device can continue to be used or prevent users from using it, ensuring the safety of use and eliminating potential safety hazards. In addition, the leakage current detection and interruption device provided by embodiments of the present invention has a simple circuit structure, low cost and high safety.

### BRIEF DESCRIPTION OF DRAWINGS

Preferred embodiments of the present invention are described with reference to the drawings. These drawings explain the embodiments and their operating principle, and only illustrate structures that are necessary to the understanding of the invention. These drawings are not to scale. In the drawings, like features are designated by like reference symbols. In the block diagrams, lines between blocks represent electrical or magnetic coupling of the blocks; the absence of lines between blocks does not mean the lack of coupling.

FIG. 1 is a block diagram of an LCDI device according to embodiments of the present invention.

FIG. 2 is a circuit diagram of an LCDI device according to a first embodiment of the present invention.

FIG. 3 is a circuit diagram of an LCDI device according to a second embodiment of the present invention.

FIG. 4 is a circuit diagram of an LCDI device according to a third embodiment of the present invention.

FIG. 5 is a circuit diagram of an LCDI device according to a fourth embodiment of the present invention.

FIG. 6 is a circuit diagram of an LCDI device according to a fifth embodiment of the present invention.

### DETAILED DESCRIPTION OF THE INVENTION

Preferred embodiments of the present invention are described below with reference to the drawings. These drawings and descriptions explain embodiments of the invention but do not limit the invention. The described embodiments are not all possible embodiments of the present invention. Other embodiments are possible without departing from the spirit and scope of the invention, and the structure and/or logic of the illustrated embodiments may be modified. Thus, it is intended that the scope of the invention is defined by the appended claims.

Before describing the embodiments, some terms used in this disclosure are defined here to help the reader better understand this disclosure.

In this disclosure, terms such as “connect”, “couple”, “link” etc. should be understood broadly, without limitation to physical connection or mechanical connection, but can include electrical connection, and can include direct or indirection connections. Terms such as “a” and “one” do not limit the quantity, and refers to “at least one”.

In the descriptions below, terms such as “including” are intended to be open-ended and mean “including without limitation”, and can include other contents. “Based on” means “at least partly based on.” “An embodiment” means “at least one embodiment.” “Another embodiment” means “at least another embodiment,” etc. In this disclosure, the above terms do not necessarily refer to the same embodiments. Further, the various features, structures, materials or characteristics may be suitably combined in any of the one or more embodiments. Those of ordinary skill in the art may combine the various embodiments and various characteristics of the embodiments described herein when they are not contrary to each other.

Embodiments of the present invention provide a leakage current detection and interruption device (LCDI device) (also referred to as a leakage detection protection device). The device includes a functional redundancy module, which can provide a redundancy function for at least one component in a monitoring module and/or a drive module, so as to provide the same function as the at least one component when it fails (i.e. to provide a replacement function), so that the product can continue to be used or prevent users from using it, ensuring safety and eliminating potential safety hazards. In addition, the leakage detection protection device according to embodiments of the present invention has a simple circuit structure, low cost and high safety.

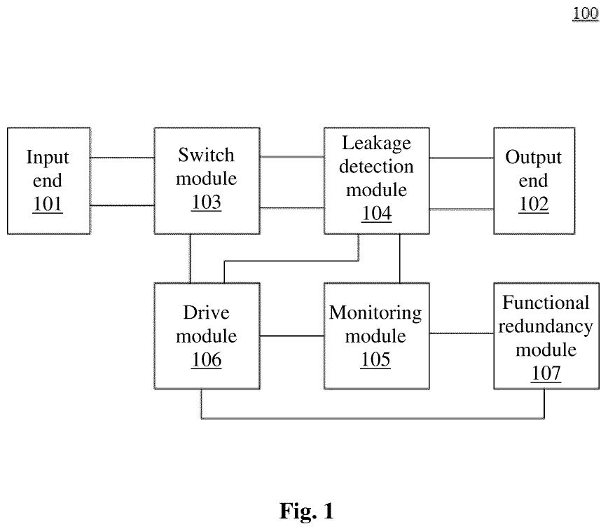

FIG. 1 is a block diagram of a leakage detection protection device according to embodiments of the present invention.

As shown in FIG. 1, the leakage detection protection device 100 includes a switch module 103, a leakage detection module 104, a monitoring module 105, a drive module 106 and a functional redundancy module 107. The switch module 103 controls the power connection between the input end 101 and the output end 102 of the power lines. The leakage detection module 104 includes a first leakage detection line and a second leakage detection line connected in series at one end. The first leakage detection line covers the first current-carrying line in the power line and detects a leakage current signal on the first current-carrying line. The second leakage detection line covers the second current-carrying line in the power line and detects a leakage current signal on the second current-carrying line. The leakage detection module 104 generates a leakage fault signal when the first leakage detection line and/or the second leakage detection line detects a leakage current signal. The monitoring module 105 is connected in series with the first leakage detection line and the second leakage detection line and is connected to the first current-carrying line and the second current-carrying line, and detects whether the first leakage detection line and/or the second leakage detection line has a fault, and generates a detection fault signal when a fault occurs. The drive module is connected to the switch module 103, the leakage detection module 104 and the monitoring module 105, and drives the switch module 103 to disconnect the power connection in response to the leakage fault signal and/or the detection fault signal. The functional redundancy module 107 includes at least one redundant element. The at least one redundant element is connected in series or in parallel with at least one element in the monitoring module 105 and/or the drive module 106, thereby providing the same function as the at least one element when a fault occurs in the at least one element (i.e. to provide a replacement function).

Whether to connect the redundant element in series or in parallel with the at least one element can be determined by determining whether the at least one element will bring a safety hazard to the user when a short circuit fault or an open circuit fault occurs. For example, if a certain element may cause a safety hazard to the user when a short circuit fault occurs in it, then the redundant element is connected in series with the clement to avoid the safety hazard. Similarly, if a certain element may cause a safety hazard to the user when an open circuit fault occurs in it, then the redundant element is connected in parallel with the element to avoid the safety hazard. If a certain element may cause a safety hazard to the user when either a short circuit fault or an open circuit fault occurs in it, then two redundant elements may be employed, which are respectively connected in series and in parallel with the element. In this case, whether to connect the redundant element in series or in parallel with the element may alternatively be determined based on the possibility of the short circuit fault or the open circuit fault of the element, so as to avoid the safety hazard and at the same time reduce the volume and cost of the leakage protection device. Each element and the redundant element connected in series or in parallel with it are in a corresponding relationship, which can be one or more of the elements such as resistors, capacitors, inductors, diodes, voltage regulator diodes, semiconductor elements, etc. Each component and the redundant component connected in series or in parallel with it may be components of the same type, for example, they are both resistors, or both capacitors, or both diodes, or both Zener diodes; or they may be components of different types, as long as the redundant component provides the same function as the corresponding component (i.e., the component connected in series or in parallel with it).

In the leakage detection protection device 100, because the functional redundancy module 107 includes at least one redundant element, it can provide redundancy functions for at least one element in the monitoring module 105 and/or the drive module 106, so as to provide the same function as the at least one element when the at least one element fails, so that the LCDI device can continue to be used or can prevent users from using it, thereby ensuring the safety and eliminating potential safety hazards.

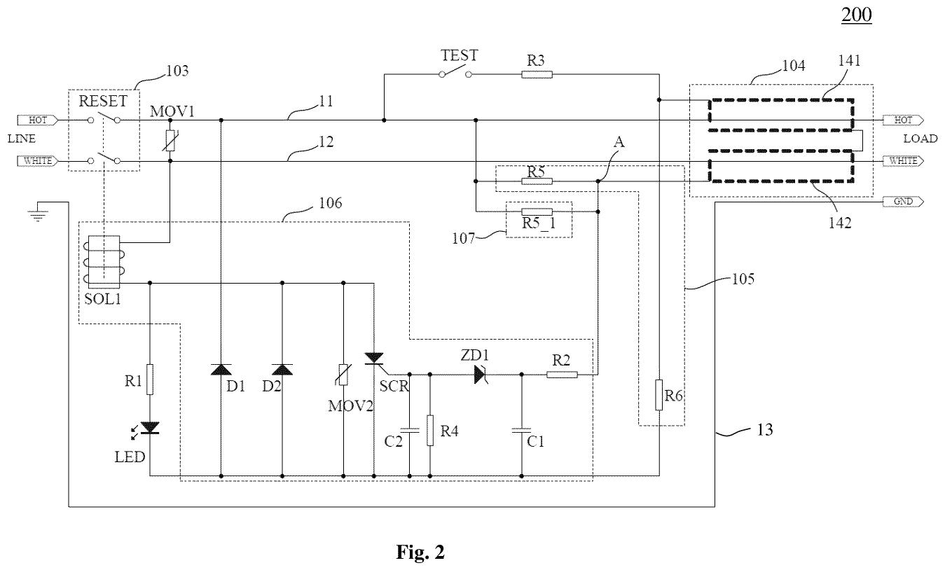

FIG. 2 shows a circuit diagram of a leakage detection protection device according to a first embodiment of the present invention. As shown in FIG. 2, the leakage detection protection device 200 includes a switch module 103, a leakage detection module 104, a monitoring module 105, a drive module 106, and a functional redundancy module 107. As shown in FIG. 2, the switch module 103 includes a reset switch RESET for controlling the power connection between the input end LINE and the output end LOAD of the power lines. The power lines include a first current-carrying line 11 (hot line), a second current-carrying line 12 (neutral line) and a third current-carrying line 13 (ground line). The leakage detection module 104 includes a first leakage detection line 141 and a second leakage detection line 142. The first leakage detection line 141 covers the first current-carrying line 11 and is used to detect the leakage current signal on the first current-carrying line 11, and the second leakage detection line 142 covers the second current-carrying line 12 and is used to detect the leakage current signal on the second current-carrying line 12.

As shown in FIG. 2, the first leakage detection line 141 and the second leakage detection line 142 are connected in series at one end. The monitoring module 105 includes a resistor R5 (first resistor) and a resistor R6 (second resistor) for detecting whether the first leakage detection line 141 and/or the second leakage detection line 142 has a fault, and generating a detection fault signal when a fault occurs. One end of the resistor R5 is connected to the first current-carrying line 11, the reset switch RESET and the test switch TEST, and the other end thereof is connected to the other end of the second leakage detection line 142 and one end of the resistor R2 (fifth resistor) in the drive module 106 at a connection point A. One end of the resistor R6 is connected to the other end of the first leakage detection line 141 and the resistor R3, and the other end thereof is connected to one end of the capacitor C1 (first capacitor) in the drive module 106. The functional redundancy module 107 includes a resistor R5_1 (third resistor) connected in series with the resistor R5.

In addition to the resistor R2 and the capacitor C1, the drive module 106 also includes a solenoid SOL1, a silicon-controlled rectifier SCR (semiconductor element), a diode D1 (first diode), a diode D2 (second diode), a capacitor C2 (second capacitor), a resistor R4 and a voltage-stabilizing diode (Zener diode) ZD1 (first voltage-stabilizing diode). In the drive module 106, the anodes of the diodes D1 and D2 are connected to the cathode of the SCR, the cathode of the diode D1 is connected to the first current-carrying line 11 and the reset switch RESET, and the cathode of the diode D2 is connected to one end of the solenoid SOL1. The anode of the voltage-stabilizing diode ZD1 is connected to the control electrode of the SCR, and the cathode is connected to the other end of the resistor R2. The two ends of the capacitor C1 are respectively connected to the cathode of the voltage-stabilizing diode ZD1 and the cathode of the thyristor SCR. The two ends of the capacitor C2 and the resistor R4 are respectively connected to the control electrode and cathode of the SCR. The anode of the SCR is also connected to one end of the solenoid SOL1. The other end of the solenoid SOL1 is connected to the second current-carrying line 12 and the reset switch RESET. The solenoid SOL1 is used to generate an electromagnetic force for driving the switch module 103. The SCR causes the solenoid SOL1 to generate the electromagnetic force in response to the leakage fault signal and/or the detection fault signal.

When all components are working properly, and the first leakage detection line 141 and the second leakage detection line 142 are both working properly (no open circuit), the current of the first current-carrying line 11 flows through the loop of R5-142-141-R6-D2-SOL1 to the second current-carrying line 12. By setting the resistance values of resistors R5 and R6, the point A is limited to a relatively low voltage, which is lower than the threshold voltage of the Zener diode ZD1, thereby limiting the voltage of the control electrode of the SCR to an extremely low level, which is not enough to trigger the SCR to turn on to cause electromagnetic force to be generated in the solenoid SOL1. At this time, the switch module 103 is in a closed state, and the LCDI device is powered on and used normally.

When all components are working normally, when the first current-carrying line 11 and/or the second current-carrying line 12 generates a leakage current signal, the voltage at point A rises, and via the path 11-141-142-R2-ZD1, triggers the SCR to turn on. A current loop is formed through 12-SOL1-SCR-D1-11, and a large current flows through solenoid SOL1, which in turn generates a sufficiently large magnetic field to drive the reset switch RESET of the switch module 103 to disconnect, thereby cutting off the power connection between the input end LINE and the output end LOAD. Therefore, the device can detect the leakage current signal on the first current-carrying line 11 and the second current-carrying line 12.

When all components are working normally, if the first leakage detection line 141 and/or the second leakage detection line 142 has an open circuit fault, the resistor R6 loses its voltage dividing function, the potential of point A rises, and via the path 11-R5-R2-ZD1, triggers the SCR to turn on. As a result, a large current flows through the solenoid SOL1, generating a sufficiently large magnetic field to drive the reset switch RESET of the switch module 103 to disconnect, thereby cutting off the power connection between the input end LINE and the output end LOAD. Therefore, the device can detect whether the first leakage detection line 141 and/or the second leakage detection line 142 has an open circuit fault.

In the case where the functional redundancy module 107 is not provided, an open circuit fault of the resistor R5 will cause a safety hazard. Specifically, when the first current-carrying line 11 and/or the second current-carrying line 12 generates a leakage current signal, point A will remain at a low voltage, unable to trigger the SCR to turn on, and the solenoid SOL1 will not be able to drive the reset switch RESET of the switch module 103 to disconnect, and the input end LINE and the output end LOAD will remain electrically connected. Similarly, when the first leakage detection line 141 and/or the second leakage detection line 142 has an open circuit fault, point A will also remain at a low voltage, unable to trigger the SCR to turn on, and the input end LINE and the output end LOAD will remain electrically connected. In other words, the leakage detection device 200 loses the leakage protection function or the function of detecting whether an open circuit fault occurred in the leakage detection lines.

In this embodiment, a functional redundancy module 107 is provided, which includes a resistor R5_1 (third resistor) connected in parallel with the resistor R5. The parameters of the resistors R5 and R5_1 can be adjusted so that the leakage detection protection device 200 can work normally when the resistor R5 has no fault. When the resistor R5 has an open circuit fault, the resistor R5_1 connected in parallel with it still works normally, so a redundancy function can be provided for the resistor R5. When the first current-carrying line 11 and/or the second current-carrying line 12 generates a leakage current signal, or when the first leakage detection line 141 and/or the second leakage detection line 142 has an open circuit fault, the voltage at point A rises, and via the path 11-R5_1-R2-ZD1, triggers the SCR to turn on, so that the solenoid SOL1 drives the switch module 103 to disconnect, cutting off the power connection between the input end LINE and the output end LOAD, thereby eliminating potential safety hazards.

Similarly, an open circuit fault of the resistor R6 can also bring potential safety hazards. Therefore, in other embodiments, a redundant resistor (fourth resistor) connected in parallel with the resistor R6 may be provided to provide a redundancy function for the resistor R6. Depending on the actual situation (such as the possibilities of open circuit faults of resistors R5 and R6), the functional redundancy module 107 may be set to include only a redundant resistor of the resistor R6, or may include redundant resistors of both resistor R6 and resistor R5.

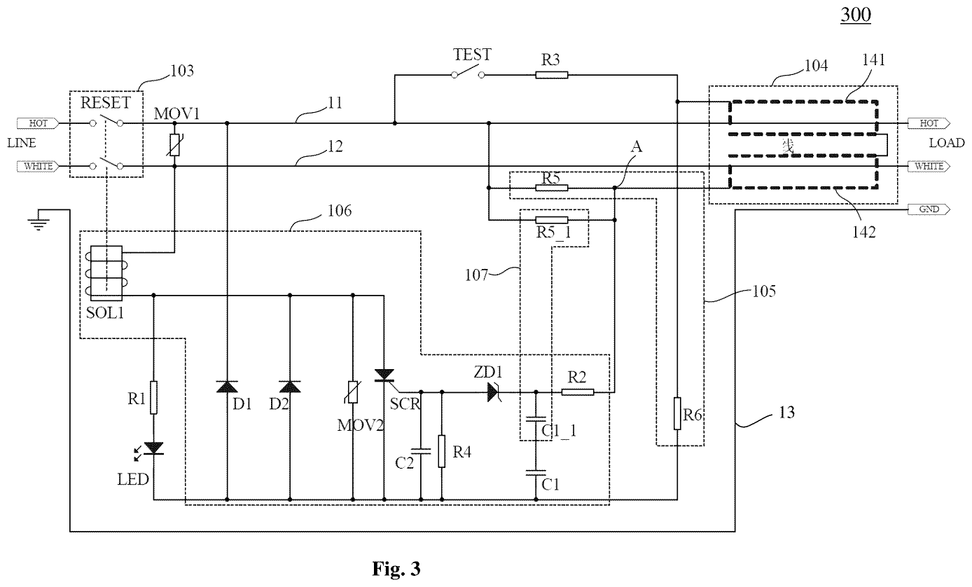

FIG. 3 shows a circuit diagram of a leakage detection protection device according to a second embodiment of the present invention. Compared with the embodiment of FIG. 2, the difference mainly lies in the functional redundancy module 107. In the embodiment of FIG. 3, the functional redundancy module 107 includes a resistor R5_1 connected in parallel with the resistor R5 and a capacitor C1_1 (third capacitor) connected in series with capacitor C1.

When all components are working properly, the working principle of the leakage detection protection device 300 is the same as that of the leakage detection protection device 200, which will not be described in detail. When the resistor R5 has an open circuit fault, the resistor R5_1 can provide redundancy in the manner described earlier.

In the case where the redundant capacitor C1_1 is not provided, a short circuit of the capacitor C1 may cause a safety hazard. Specifically, when the first current-carrying line 11 and/or the second current-carrying line 12 generates a leakage current signal, or when the first leakage detection line 141 and/or the second leakage detection line 142 has an open circuit fault, the capacitor C1 cannot provide a charging/discharging function, and thus cannot trigger the SCR to turn on. As a result, the solenoid SOL1 cannot drive the reset switch RESET of the switch module 103 to disconnect, and the input end LINE and the output end LOAD remain electrically connected.

In this embodiment, the functional redundancy module 107 includes a capacitor C1_1 connected in series with the capacitor C1. The parameters of the capacitors C1 and C1_1 can be adjusted so that the leakage detection protection device 300 works normally when the capacitor C1 does not have a fault. When a short circuit fault occurs in the capacitor C1, the capacitor C1_1 connected in series with it still works normally, so a redundancy function can be provided for the capacitor C1. When the first current-carrying line 11 and/or the second current-carrying line 12 generates a leakage current signal, or when the first leakage detection line 141 and/or the second leakage detection line 142 has an open circuit fault, the SCR can be triggered to turn on, so that the solenoid SOL1 drives the switch module 103 to disconnect, cutting off the power connection between the input end LINE and the output end LOAD, thereby eliminating potential safety hazards.

Similarly, an open circuit fault of capacitor C1 can also cause potential safety hazards. Therefore, in other embodiments, capacitor C1_1 may be connected in parallel with capacitor C1 to provide a redundancy function for capacitor C1. Capacitor C1_1 may be connected in series or in parallel with capacitor C1 according to actual conditions (such as the possibilities of an open circuit fault and a short circuit fault of capacitor C1). Of course, two redundant capacitors may be provided for capacitor C1, one being connected in series with capacitor C1 and the other being connected in parallel with capacitor C1.

Similarly, a short circuit fault of capacitor C2 can also cause potential safety hazards. Therefore, in other embodiments, a redundant capacitor (fourth capacitor) connected in series with capacitor C2 may be provided to provide a redundancy function for capacitor C2. Depending on the actual situation (such as the possibilities of a short circuit fault and an open circuit fault of capacitors C1 and C2), the functional redundancy module 107 may be set to include only capacitor C1_1, or may include redundant capacitors of both capacitor C1 and capacitor C2.

Similarly, a short circuit fault or an open circuit fault of the Zener diode ZD1 can also cause potential safety hazards. Therefore, in other embodiments, a redundant Zener diode (a second Zener diode) connected in series or in parallel with the Zener diode ZD1 may be provided to provide a redundancy function for the Zener diode ZD1. The redundant Zener diode may be connected in series or in parallel with the Zener diode ZD1 according to actual conditions (such as the possibilities of a short circuit fault or an open circuit fault of the Zener diode ZD1). Of course, two redundant Zener diodes may be provided for the Zener diode ZD1, one being connected in series with the Zener diode ZD1, and the other being connected in parallel with the Zener diode ZD1.

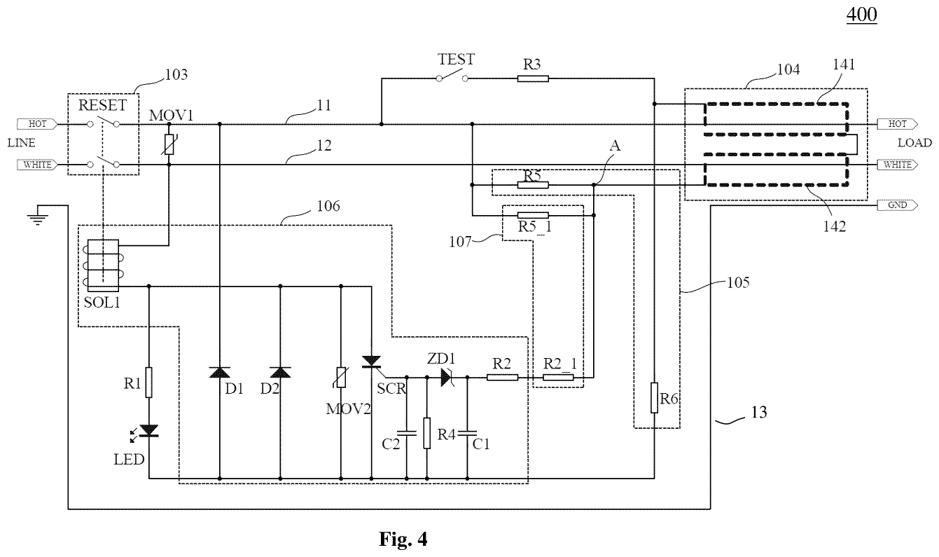

FIG. 4 shows a circuit diagram of a leakage detection protection device according to a third embodiment of the present invention. Compared with the embodiment of FIG. 2, the difference mainly lies in the functional redundancy module 107. In the embodiment of FIG. 4, the functional redundancy module 107 includes a resistor R5_1 connected in parallel with the resistor R5 and a resistor R2_1 (sixth resistor) connected in series with the resistor R2.

When all components are working properly, the working principle of the leakage detection protection device 400 is the same as that of the leakage detection protection device 200, which will not be described in detail. When the resistor R5 has an open circuit fault, the resistor R5_1 can provide redundancy in the manner described earlier.

In the case where the resistor R2_1 is not provided, a short circuit of the resistor R2 can cause a safety hazard. Specifically, when the first current-carrying line 11 or the second current-carrying line 12 generates a leakage current signal, the current in the current path is too large and will burn the capacitor C1, the voltage-stabilizing diode ZD1 or the diode D1, causing the leakage detection protection device 400 to fail to work, thus causing a safety hazard.

In this embodiment, the functional redundancy module 107 includes a resistor R2_1 connected in series with the resistor R2. The parameters of the resistors R2 and R2_1 can be adjusted so that the leakage detection protection device 400 works normally when the resistor R2 does not have a fault. When the resistor R2 has a short circuit fault, the resistor R2_1 connected in series with it still works normally, so a redundancy function can be provided for the resistor R2. When the first current-carrying line 11 or the second current-carrying line 12 generates a leakage current signal, the resistor R2_1 can ensure that the current in the current path is not too large, so that the drive module 106 works normally, cutting off the power connection between the input end LINE and the output end LOAD, thereby eliminating potential safety hazards.

Similarly, a short circuit fault of the resistor R2 may result in the inability to trigger the SCR, which may also cause potential safety hazards. Therefore, in other embodiments, the resistor R2_1 may be connected in parallel with the resistor R2 to provide a redundancy function for the resistor R2. The resistor R2_1 may be connected in series or in parallel with the resistor R2 according to actual conditions (such as the possibilities of an open circuit fault and a short circuit failure of the resistor R2). Of course, two redundant resistors may be provided for the resistor R2, one being connected in series with the resistor R2, and the other being connected in parallel with the resistor R2.

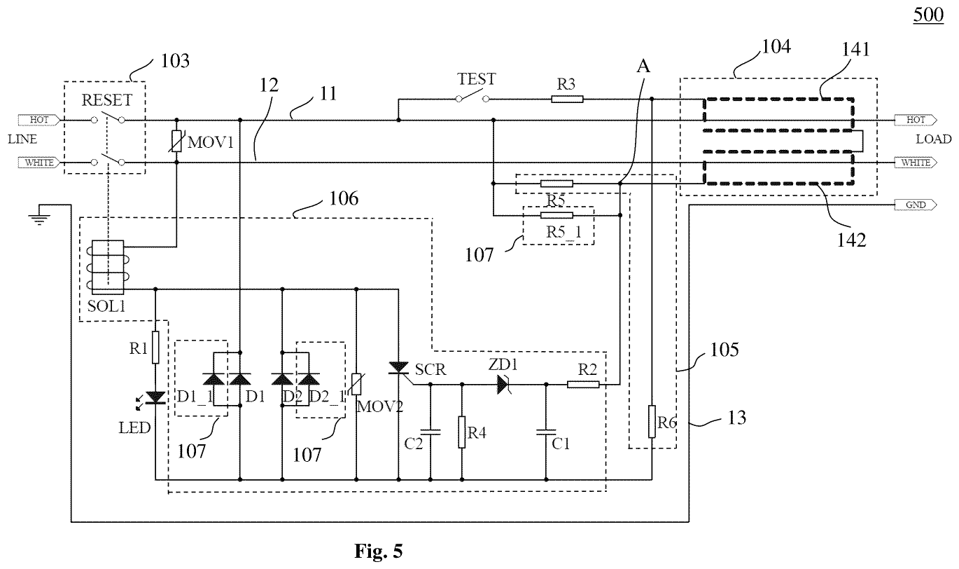

FIG. 5 shows a circuit diagram of a leakage detection protection device according to a fourth embodiment pf the present invention. Compared with the embodiment of FIG. 2, the difference mainly lies in the functional redundancy module 107. In the embodiment of FIG. 5, the functional redundancy module 107 includes a resistor R5_1 connected in parallel with the resistor R5, a diode D1_1 (a third diode) connected in parallel with the diode D1, and a diode D2_1 (a fourth diode) connected in parallel with the diode D2.

When all components are working properly, the working principle of the leakage detection protection device 500 is the same as that of the leakage detection protection device 200, which will not be described in detail. When the resistor R5 has an open circuit fault, the resistor R5_1 can provide redundancy in the manner described earlier.

In the case where diodes D1_1 and D1_2 are not provided, an open circuit fault of diode D1 or D2 can cause potential safety hazards. Specifically, if an open circuit fault occurs in diode D1, when a leakage current signal is generated on the first current-carrying line 11 or the second current-carrying line 12, or when an open circuit fault occurs in the first leakage detection line 141 and/or the second leakage detection line 142, although the SCR can be triggered to conduct, a current path cannot be formed, and the solenoid SOL1 cannot drive the reset switch RESET of the switch module 103 to disconnect, and the input end LINE and the output end LOAD remain electrically connected. If diode D2 has an open circuit fault, when a leakage current signal is generated on the first current-carrying line 11, or when the first leakage detection line 141 and/or the second leakage detection line 142 has an open circuit fault, the reset switch RESET of the switch module 103 cannot be driven to disconnect, and the input end LINE and the output end LOAD remain electrically connected.

In this embodiment, the functional redundancy module 107 includes a diode D1_1 connected in parallel with the diode DI and a diode D2_1 connected in parallel with the diode D2. When the diode D1 and/or D2 has an open circuit fault, the diodes D1_1 and/or D2_1 connected in parallel therewith still work normally, so that a redundancy function can be provided for the diodes D1 and D2. When a leakage current signal is generated on the first current-carrying line 11 and/or the second current-carrying line 12, or when the first leakage detection line 141 and/or the second leakage detection line 142 has an open circuit fault, the SCR can be triggered to turn on, so that the solenoid SOL1 drives the switch module 103 to disconnect, cutting off the power connection between the input end LINE and the output end LOAD, thereby eliminating potential safety hazards.

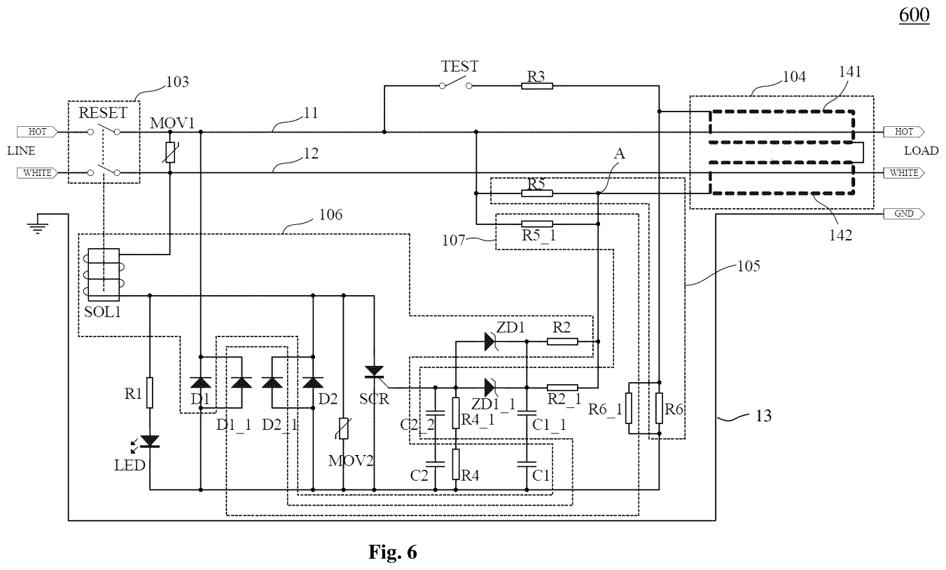

FIG. 6 shows a circuit diagram of a leakage detection protection device according to a fifth embodiment of the present invention. Compared with the embodiment of FIG. 2, the difference mainly lies in the functional redundancy module 107. In the embodiment of FIG. 6, the functional redundancy module 107 includes a resistor R5_1 connected in parallel with the resistor R5, a resistor R6_1 connected in parallel with the resistor R6, a resistor R2_1 connected in parallel with the resistor R2, a resistor R4_1 connected in series with the resistor R4, a Zener diode ZD1_1 connected in parallel with the zener diode ZD1, a capacitor C1_1 connected in series with the capacitor C1, a capacitor C2_2 connected in series with the capacitor C2, a diode D1_1 connected in parallel with the diode D1, and a diode D2_1 connected in parallel with the diode D2.

Referring to the earlier descriptions, the resistors R5_1, R6_1, R2_1, R4_1, the Zener diode ZD1_1, the capacitors C1_1, C2_2, and the diodes D1_1 and D2_1 respectively provide redundancy functions for the resistors R5, R6, R2, R4, the Zener diode ZD1, the capacitors C1, C2, and the diodes DI and D2. In the event one or more of the resistors R5, R6, R2, R4, the Zener diode ZD1, the capacitors C1, C2, and the diodes D1 and D2 have a short circuit fault or an open circuit fault, the corresponding redundant components can work normally, thereby eliminating the potential safety hazard.

Some additional aspects of the present invention provide an electrical power connection device, which includes a body and a leakage current detection and protection device according to any one of the above embodiments disposed inside the body.

Other additional aspects of the present invention provide an electrical appliance, which includes an electrical load, and an electrical power connection device connected between a power supply and the load to supply power to the load, where the electrical power connection device employs a leakage current detection and protection device according to any one of the above embodiments.

While the present invention is described above using specific examples, these examples are only illustrative and do not limit the scope of the invention. It will be apparent to those skilled in the art that various modifications, additions and deletions can be made to the LCDI device of the present invention without departing from the spirit or scope of the invention.

1. A leakage current detection and interruption device, comprising:
power supply lines including a first current-carrying line and a second current-carrying line, having an input end and an output end;
a switch module, configured to control a power connection between the input end and the output end;
a leakage detection module, including a first leakage detection line and a second leakage detection line connected in series at one end, wherein the first leakage detection line covers the first current-carrying line and is configured to detect a leakage current signal on the first current-carrying line, and the second leakage detection line covers the second current-carrying line and is configured to detect a leakage current signal on the second current-carrying line, and the leakage detection module is configured to generate a leakage fault signal when the first leakage detection line and/or the second leakage detection line detects the leakage current signal;
a monitoring module, connected in series with the first leakage detection line and the second leakage detection line and connected to the first current-carrying line and the second current-carrying line, and configured to detect whether the first leakage detection line and/or the second leakage detection line has a fault and to generate a detection fault signal when a fault occurs;
a drive module, connected to the switch module, the leakage detection module and the monitoring module, and configured to drive the switch module to disconnect the power connection in response to the leakage fault signal and/or the detection fault signal; and
a functional redundancy module, including at least one redundant element, wherein the at least one redundant element is connected in series or in parallel with at least one element of the monitoring module and/or the drive module and configured to provide a replacement function that replaces the at least one element when the at least one element has a fault.

2. The leakage current detection and interruption device of claim 1, wherein the monitoring module includes a first resistor, wherein one end of the first resistor is connected to another end of the first current-carrying line, and another end of the first resistor is connected to another end of the second leakage detection line and connected to the drive module, and wherein the at least one redundant element includes a third resistor connected in parallel with the first resistor.

3. The leakage current detection and interruption device of claim 2, wherein the monitoring module includes a second resistor, wherein one end of the second resistor is connected to the other end of the first leakage detection line and another end of the second resistor is connected to the drive module, and wherein the at least one redundant element includes a fourth resistor connected in parallel with the second resistor.

4. The leakage current detection and interruption device of claim 1, wherein the drive module includes:
a solenoid configured to generate an electromagnetic force for driving the switch module; and
at least one semiconductor element, connected in series with the solenoid, wherein the semiconductor element is triggered to turn on in response to the leakage fault signal and/or the detection fault signal, wherein the solenoid generates the electromagnetic force when the semiconductor is turned on.

5. The leakage current detection and interruption device of claim 4, wherein the drive module further includes a first diode, wherein an anode of the first diode is connected to a cathode of the at least one semiconductor element and a cathode of the first diode is connected to the first current-carrying line, and the at least one redundant element includes a third diode connected in parallel with the first diode.

6. The leakage current detection and interruption device of claim 5, wherein the drive module further includes a second diode, wherein an anode of the second diode is connected to a cathode of the at least one semiconductor element and a cathode of the second diode is connected to the solenoid, and wherein the at least one redundant element includes a fourth diode connected in parallel with the second diode.

7. The leakage current detection and interruption device of claim 4, wherein the drive module includes a first capacitor and a first voltage regulator diode, wherein an anode of the first voltage regulator diode is connected to a control electrode of the at least one semiconductor element, and a cathode of the first voltage regulator diode is connected to the leakage detection module and the monitoring module, and two ends of the first capacitor are respectively connected to a cathode of the at least one semiconductor element and the cathode of the first voltage regulator diode, and wherein the at least one redundant element includes:
a third capacitor connected in series or in parallel with the first capacitor; and/or
a second voltage regulator diode connected in series or in parallel with the first voltage regulator diode.

8. The leakage current detection and interruption device of claim 7, wherein the drive module further includes a fifth resistor, wherein one end of the fifth resistor is connected to the cathode of the first voltage regulator diode and one end of the first capacitor, and another end of the fifth resistor is connected to the monitoring module, and wherein the at least one redundant element includes a sixth resistor is connected in series or in parallel with the fifth resistor.

9. The leakage current detection and interruption device of claim 4, wherein the drive module includes a second capacitor, wherein two ends of the second capacitor are respectively connected to a cathode and a control electrode of the at least one semiconductor element, and wherein the at least one redundant element includes a fourth capacitor connected in series with the second capacitor.

10. An electrical power connection device, comprising:
a body; and
a leakage current detection and interruption device of claim 1, disposed inside the body.

11. An electrical appliance, comprising:
an electrical load; and
an electrical power connection device of claim 10 connected between a power supply and the electrical load, configured to supply power to the electrical load.
